(19) United States
(12) Patent Application Publication
(10) Pub. No.: US 2002/0140492 A1
(43) Pub. Date: Oct. 3, 2002

(54) Matching circuit and semiconductor device

(76) Inventors: Takao Ishida, Tokyo (JP); Yoshihiro Tsukahara, Tokyo (JP)

Correspondence Address: LEYDIG VOIT & MAYER, LTD, 700 THIRTEENTH ST. NW, SUITE 300, WASHINGTON, DC, 20005-3960, US

(21) Appl. No.: 09/877,037

(22) Filed: Jun. 11, 2001

(30) Foreign Application Priority Data
Jan. 26, 2001 (JP) 2001-019243

(51) Int. Cl. H03K 17/16

(52) U.S. Cl. 327/382

(57) ABSTRACT

A matching circuit that can protect a high frequency circuit from degradation in both output and efficiency, as well as from an increase of noise, changes of a frequency band even when an MIM insulation film thickness L around a subject transistor changes due to an unevenness among fabrication processes, thereby an electrical property of the transistor never changes among products, and provide a semiconductor device that employs such the matching circuit. An MIM capacity C1 is connected to an input side of the transistor so as to be combined with an input capacity of the transistor, thereby changes of the MIM insulation film thickness L can be eliminated automatically. The MIM capacity C1 changes contrarily to the changes of the MIM insulation film thickness L. That is, it is possible to realize a matching circuit that can absorb fluctuation of electric characteristics of the subject transistor automatically while the fluctuation of electric characteristics of the transistor are caused by changes of the MIM insulation film thickness L around the transistor to occur due to the unevenness among fabrication processes. In addition, in the case where the matching circuit is provided with a bias circuit, it is possible to obtain a high frequency circuit that can operate stably in a wide frequency band.

### BACKGROUND OF THE INVENTION

1. Field of the Invention

The present invention relates to a matching circuit and a semiconductor device fabricated with use of the matching circuit. More particularly, the present invention relates to a matching circuit, as well as an MMIC (Monolithic Microwave Integrated Circuit) formed together with the matching circuit on one and the same substrate and used for high frequencies.

2. Description of Related Art

In mobile radio communications between such mobile terminals as portable phones, both communication speed and communication capacity have been increased along with an increase of the information content. That is, the use of higher frequencies is required as those communication frequencies. In the case where a high frequency is used as a communication frequency, the importance of a matching circuit for matching between input and output parts or between transistors is becoming higher. This is because a high frequency circuit is degraded in both output and efficiency, as well as its noise increases and the frequency band is changed when the capacity value of the capacitor, the inductance value of the inductor, or the electrical property of the transistor included in this matching circuit is shifted from the design value. Especially, this phenomenon appears remarkably in frequency bands referred to as millimeter wave bands over 30GHz.

In the case where a high frequency band is used, a matching circuit must be formed around a pole of each transistor, since frequency wavelengths are short in such high frequency bands as millimeter wave bands. In spite of this, it is actually impossible to form such a matching circuit outside a semiconductor substrate. Generally, therefore, a monolithic microwave integrated circuit (MMIC) is employed for mobile radio communications, since it is formed together with a matching circuit on the same substrate. The MMIC mentioned here means a plurality of microwave circuits formed on one semiconductor chip after the respective microwave circuits are assembled with parts.

FIGS. 10(A) and 10(B) show two examples of a conventional input side matching circuit. In FIG. 10(A), reference numeral 5 denotes an input terminal, reference numerals 10 and 12 denote lines, reference numeral 26 denotes a transistor, reference character L1 denotes an open stub capacity (of the line 10), and reference character L2 denotes an inductance of the line 12. In FIG. 10(B), reference numeral 5 denotes an input terminal, reference numeral 12 denotes a line, reference numeral 26 denotes a transistor, reference numeral 38 denotes a capacitor, reference character C1 denotes an MIM capacity (a total capacity of the three layers; metal, insulator, and metal layers) of the capacitor 38, and reference character L2 denotes an inductance of the line 12. Reference character a denotes a point for denoting a gate-source capacity when the point is viewed from the input side of the transistor 26, reference character c denotes a point when it is viewed together with the inductance L2, and reference character d denotes a point when it is viewed together with the open stub capacity L1 from the input terminal 5. As shown in FIGS. 10(A) and 10(B), the capacitor C1, etc. having an MIM capacity respectively and the transistor 26 are patterned on the same substrate.

FIG. 11 is a Smith chart for an input side matching circuit shown in FIG. 10. In FIG. 11, the same reference numerals are given to the same items as those shown in FIG. 10, avoiding redundant description. In FIG. 11, reference symbol Cgs denotes a simplified gate-source capacity seen typically in an input side equivalent circuit of the transistor 26. As shown in FIG. 11, the impedance, at the time of viewing it from the input terminal 5 side in the design stage, moves to the point d on the Smith chart. The point d denotes 50Ω obtained by combining the gate-source capacity Cgs, the inductance L2, and the open stub capacity L1 or MIM capacity C1.

As described above, the MMIC enables both of the capacitor C1 having an MIM capacity and the transistor 26 to be formed on the same substrate, so an excessive insulation film (MIM insulation film) is formed unavoidably around the transistor 26 due to the fabrication method. Consequently, this excessive insulation film generates a parasitic capacity, causing the electrical property of the transistor 26 to be changed. Table 1 shows results of a comparison performed with respect to such the parasitic capacity at input side and output side of the transistor 26 between when an MIM insulation film is formed and when not formed around the transistor 26.

TABLE 1

| | When no MIM | |
|---|---|---|
| | insulation film is | When an MIM |
| | formed around | insulation film is formed |
| Example in HEMT | transistor 26 | around transistor 26 |
| Capacity Cgs[pF/mm] at | 0.73 | 0.89 |
| input side of transistor | | |
| 26 | | |
| Capacity Cgd[pF/mm] at | 0.16 | 0.22 |
| output side of transistor | | |
| 26 | | |

As shown in Table 1, the capacity Cgs[pF/mm] at the input side of the transistor 26 is 0.73[pF/mm] when no MIM insulation film is formed around the transistor 26 while it becomes 0.89[pF/mm] when an MIM insulation film is formed around the transistor 26. The capacity Cgs[pF/mm] at the output side of the transistor 26 is 0.16[pF/mm] when no insulation film is formed around the transistor 26 while it becomes 0.22[pF/mm] when an MIM insulation film is formed around the transistor 26. That is, in the case where the MIM insulation film taken as an MIM capacity changes due to the unevenness among fabrication processes, the capacity components at both input and output sides of the transistor 26 are changed, thereby the matching point is shifted from the design one and the property of the subject high frequency circuit changes. Hereinafter, this high frequency circuit property change will be described with respect to the input side impedance with reference to the Smith chart shown in FIG. 11. In FIG. 11, when the MIM insulation film is thick, the input side capacity Cgs of the transistor 26 increases, so that the point a on the design is shifted to the point a′ and the point c is shifted to the point c′ due to the inductance L2. The input side impedance obtained when the inductance L2 is combined with the open stub capacity L1 or MIM capacity C1 is also shifted to the point d′. The impedance is thus shifted from the matching point.

On the other hand, when the matching circuit uses the MIM capacity C1, a relationship denoted by the following Equation 1 is assumed between the MIM insulation film thickness L and the MIM capacity C1.

### Equation 1

C1=ε·S/L (1)

Here, C1 denotes an MIM capacity, ε denotes an inductance rate of the MIM insulation film, S denotes a pattern area of the MIM capacitor C1, and L denotes an MIM insulation film thickness. As shown in the expression 1, when the MIM insulation film thickness L increases, the MIM capacity C1 decreases. On the Smith chart shown in FIG. 11, therefore, the input side impedance is further shifted to the point d″, thereby the impedance is further shifted from the matching point.

According to the above description, it is considered that the same phenomenon also occurs for the output side impedance when the input side capacity Cgs is replaced with the output side capacity Cgd. That is, the impedance is shifted from the matching point due to a change of the MIM insulation film thickness L.

As described above, the configuration of the conventional matching circuit has been confronted with problems that the input/output impedance of the subject high frequency circuit changes sensitively to a change of the thickness L of the MIM insulation film around the transistor, caused by the unevenness among fabrication processes. The impedance is thus shifted from the matching point. And, the high frequency circuit is degraded in both output and efficiency and noise is increased in the matching circuit. In addition, the frequency band is changed, causing the electrical property of the transistor to be changed among products.

### SUMMARY OF THE INVENTION

Under such circumstances, it is an object of the present invention to solve the above conventional problems and provide a matching circuit that can protect the high frequency circuit from degradation in both output and efficiency and suppress noise from an increase and the frequency band from changes even when the MIM insulation film thickness L changes around the transistor due to the unevenness among fabrication processes, thereby the electrical property of the transistor never changes among products. It is another object of the present invention to provide a semiconductor device that employs the matching circuit.

According to a first aspect of the present invention, there is provided a matching circuit for absorbing fluctuation of electric characteristics of a transistor, comprising: a capacitor having a capacity that increases and decreases contrarily to increment and decrement of a parasitic capacity around the transistor.

According to a second aspect of the present invention, there is provided a semiconductor device fabricated with use of the matching circuit according to the present invention, claim 1 or claim 2.

The above and other objects, effects, features and advantages of the present invention will become more apparent from the following description of the embodiments thereof taken in conjunction with the accompanying drawings.

### BRIEF DESCRIPTION OF THE DRAWINGS

FIG. 1 shows an input side matching circuit in a first embodiment of the present invention.

FIG. 2 shows an equivalent circuit for the circuit shown in FIG. 1.

FIG. 3 shows a Smith chart for describing the above change with respect an input impedance.

FIG. 4 shows a matching circuit in the second embodiment of the present invention.

FIG. 5 is a Smith chart for describing how the input impedance changes.

FIG. 6 shows a matching circuit in this third embodiment of the present invention.

FIG. 7 shows an equivalent circuit provided for the circuit shown in FIG. 6.

FIG. 8 shows a Smith chart for describing how the output impedance changes.

FIG. 9 shows a matching circuit in this fourth embodiment of the present invention.

FIG. 10(A) shows two examples of a conventional input side matching circuit

FIG. 10(B) shows two examples of a conventional input side matching circuit

FIG. 11 is a Smith chart for an input side matching circuit shown in FIG. 10.

### DETAILED DESCRIPTION OF THE PREFERRED EMBODIMENTS

Hereunder, the preferred embodiments of the present invention will be described with reference to the accompanying drawings.

### First Embodiment

As denoted by the above expression 1, when the MIM insulation film thickness L increases, the transistor input/output capacity increases while the MIM capacity C1 decreases. On the other hand, the MIM insulation film thickness L decreases, the transistor input/output capacity decreases while the MIM capacity C1 increases. The present invention can therefore eliminate changes of the MIM insulation film thickness L automatically in the case where the MIM capacity C1 is combined with the transistor input/output capacity. The changes of the MIM capacity C1 and the changes of the MIM insulation film thickness L are contrary to each other; when one increases, the other decreases.

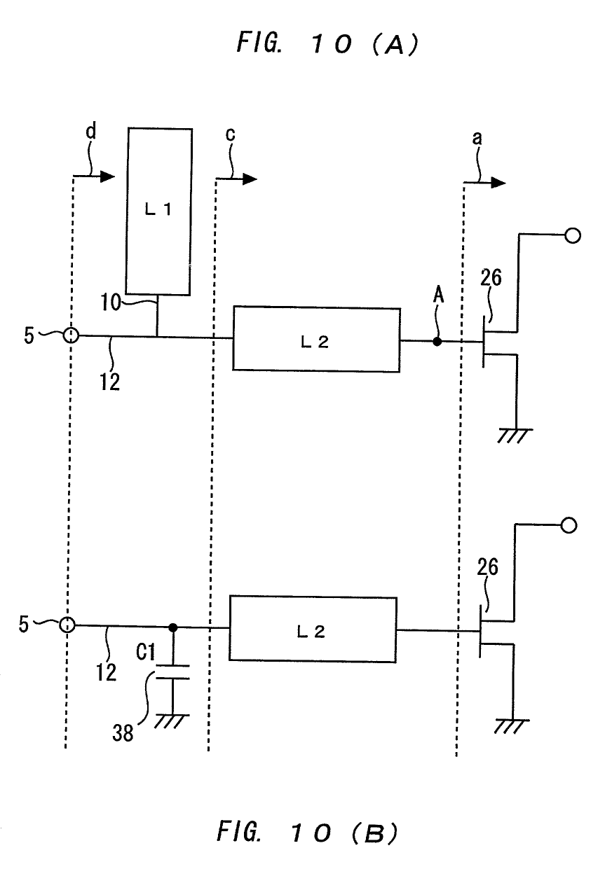

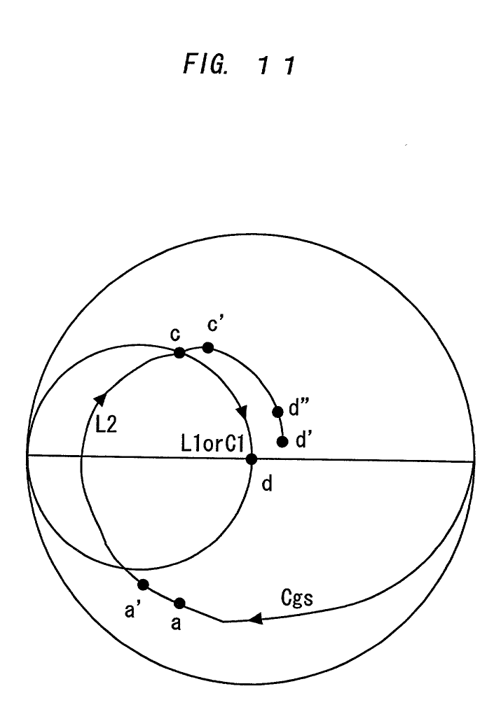

FIG. 1 shows an input side matching circuit in a first embodiment of the present invention. In FIG. 1, reference numeral 5 denotes an input terminal. Reference numerals 10 and 12 denote lines. Reference numeral 26 denotes a transistor. Reference numeral 30 denotes a capacitor. Reference character L1 denotes an open stub capacity. Reference character L2 denotes an inductance of the line 12. Reference character CA denotes an MIM capacity of the capacitor 30. Reference character a denotes a point for denoting a gate-source capacity when viewing it from the input side of the transistor 26 and reference character b denotes a point when the point is viewed together with the MIM capacity CA. Reference character c denotes a point when viewing it is viewed together with the inductance L2 and reference character d denotes a point when it is viewed together with the open stub capacity L1 from the input terminal 5. There is only a difference between the input side matching circuit shown in FIG. 1 and the conventional input side matching circuit shown in FIG. 10. The difference is that an MIM capacity CA is connected to the portion A in FIG. 10.

In FIG. 1, when a gate-source capacity Cgs of the transistor 26 is 0.1pF while the frequency f is, for example, 76 GHz, the input impedance becomes 50Ω at the MIM capacity CA=0.1pF, the inductance L2 line length=95 μm, and the line length of open stub capacity L1=255 μm.

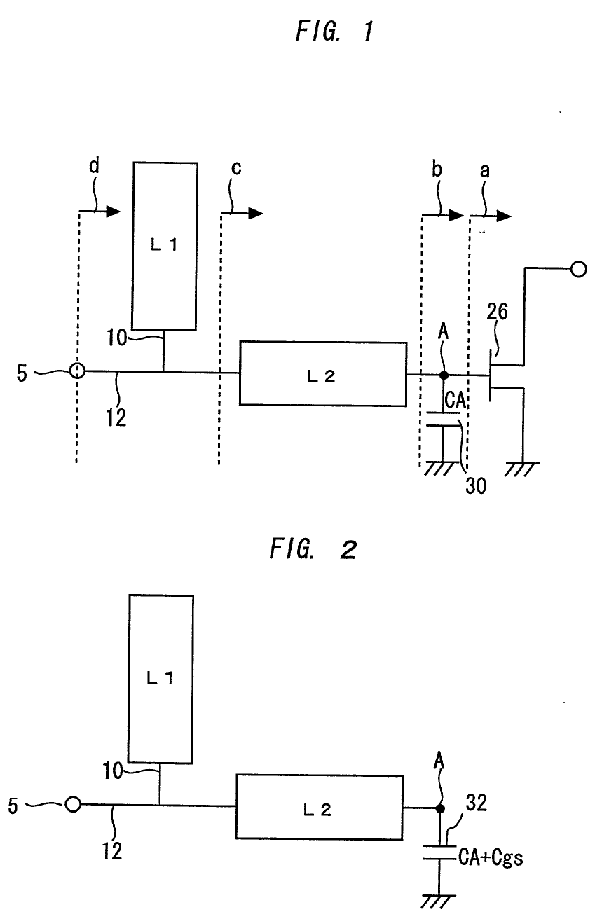

FIG. 2 shows an equivalent circuit for the circuit shown in FIG. 1. In FIG. 2, the same reference numerals/characters are given to the same items as those shown in FIG. 1, avoiding redundant description. In FIG. 2, reference numeral 32 denotes a capacitor having a total capacity of the MIM capacity CA and the gate-source capacity Cgs of the transistor 26. As described above, when the MIN insulation film thickness L increases, the gate-source capacity Cgs of the transistor 26 increases while the MIM capacity CA decreases. On the other hand, when the MIM insulation film thickness L decreases, the gate-source capacity Cgs of the transistor 26 decreases while the MIM capacity CA increases. The impedance changes such way as if the MIM capacity CA eliminates the change of the gate-source capacity Cgs of the transistor 26.

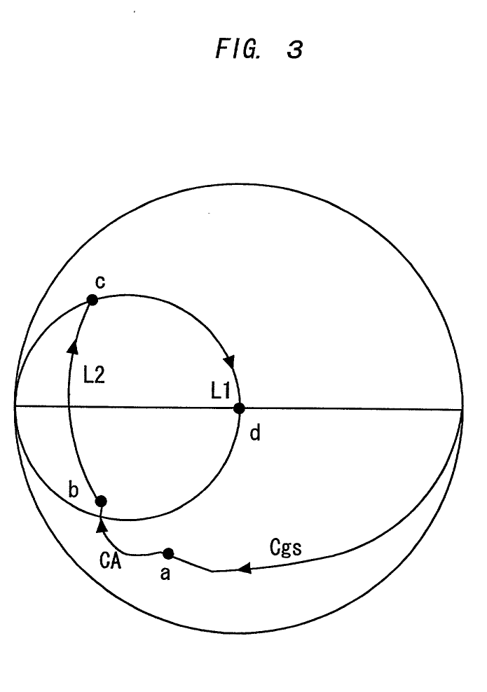

FIG. 3 shows a Smith chart for describing the above change with respect an input impedance. In FIG. 3, the same reference numerals/characters are given to the same items as those shown in FIG. 1, avoiding redundant description. On the Smith chart shown in FIG. 3, the point b denoting the capacity of the capacitor 32 (CA+Cgs) changes less with respect to the change of the MIM insulation film thickness L. Consequently, the shifting of the point d denoting the input side impedance also takes a smaller value. The open stub capacity L1 in this case does not depend on the MIM insulation film thickness L.

The above configuration is also effective for the impedance not only at the input terminal, but also for the impedance when the input side of the transistor is viewed from such a point as a portion between two amplifiers of the circuit.

According to the first embodiment described above, therefore, because the MIM capacity C1 is connected to the input side of the transistor so as to be combined with the input capacity thereof. The change of the MIM insulation film thickness L can be eliminated automatically. The change of the MIM capacity C1 and the change of the MIM insulation film thickness L are contrary to each other. That is, the first embodiment of the present invention can realize a matching circuit that can absorb fluctuation of electric characteristics of the transistor while the fluctuation of electric characteristics of the transistor is caused by the changes of the MIM insulation film thickness L to occur due to the unevenness among fabrication processes.

### Second Embodiment

In this second embodiment of the present invention, a bias circuit is added to the configuration of the matching circuit in the above first embodiment.

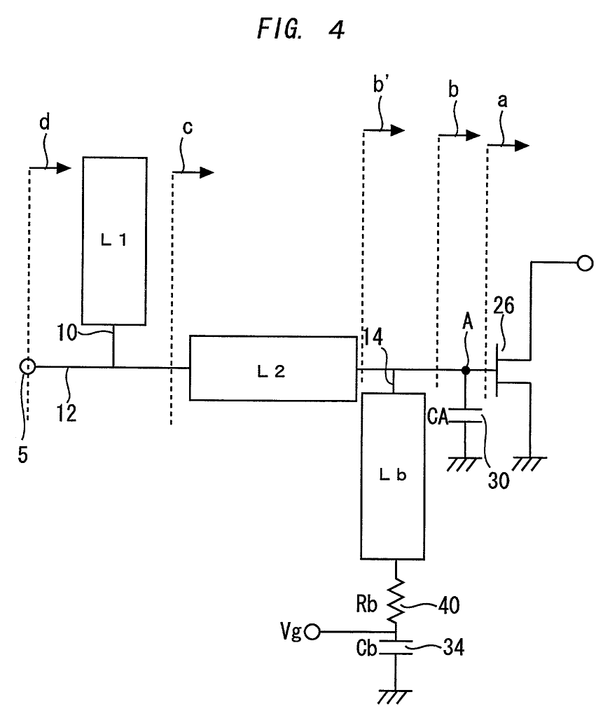

FIG. 4 shows a matching circuit in the second embodiment of the present invention. In FIG. 4, the same reference numerals/characters are given to the same items as those shown in FIG. 1, avoiding redundant description. In FIG. 4, reference numeral 14 denotes a line and reference numeral 40 denotes a resistor. Reference numeral 34 denotes a capacitor, reference character Vg denotes a gate bias terminal, reference character Lb denotes an inductance of the line 14, reference character Rb denotes a resistance value of the resistor 40, and reference character Cb denotes a capacity of the capacity 34. As shown in FIG. 4, the matching circuit in this second embodiment is provided with a bias circuit configured by the inductance Lb, the resistance value Rb, and the capacity Cb.

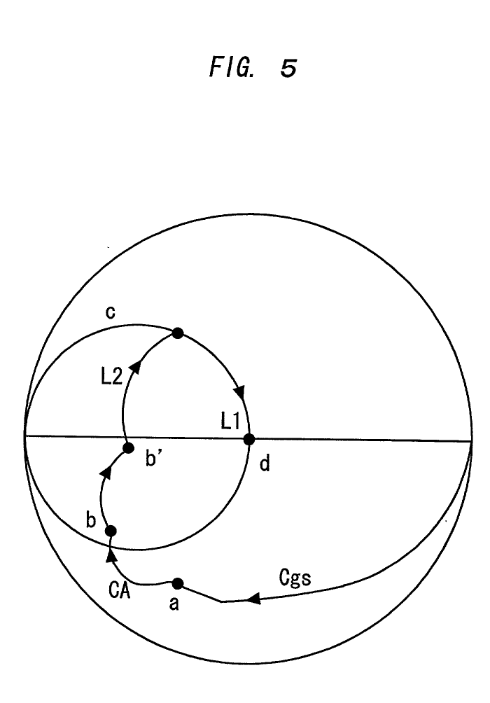

Basically, the operation of the matching circuit in the second embodiment is the same as that of the matching circuit in the first embodiment. FIG. 5 is a Smith chart for describing how the input impedance changes. In FIG. 5, the same reference numerals/characters are given to the same items as those shown in FIG. 4, avoiding redundant description. On the Smith chart shown in FIG. 5, the more the point b is shifted outwards, the narrower the band used for this circuit becomes. This is why the bias circuit configured by the inductance Lb, the resistance value Rb, and the capacity Cb as described above is employed so as to shift the point b to the point b′ located at an inner position on the chart, thereby the matching circuit can operate in a wider band.

This configuration is also effective for the impedance not only at the input terminal, but also for the impedance when the input side of the transistor is viewed from such a point as a portion between two amplifiers in the circuit.

According to the second embodiment of the present invention described above, therefore, it is possible to realize a matching circuit that can absorb the fluctuation of electric characteristics of the subject transistor automatically while the change is caused by a change of the MIM insulation film thickness L around the transistor to occur due to the unevenness among fabrication processes just like in the first embodiment. In addition, in the case where a bias circuit is added to the matching circuit, it is possible to realize a high frequency circuit that is stable in operations in a wide frequency band and less affected by the transistor's fluctuation of electric characteristics to be caused by changes of the insulation film thickness around the transistor to occur due to the unevenness among products.

### Third Embodiment

In this third embodiment, the input side element of the matching circuit in the above first embodiment is disposed at the output side. The configuration of this third embodiment is the same as that of the first embodiment, wherein the input side capacity Cgs of the transistor is replaced with the output side capacity Cgd of the transistor.

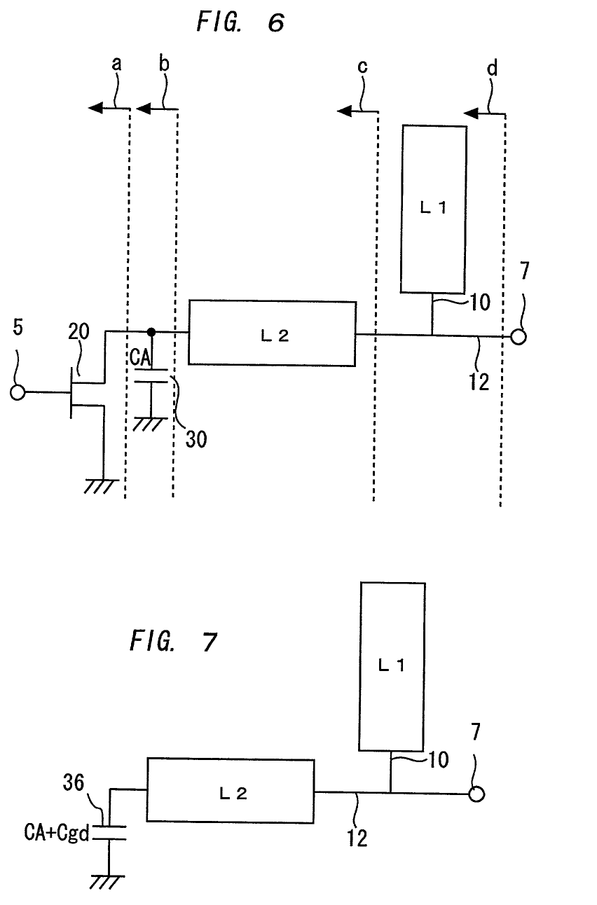

FIG. 6 shows a matching circuit in this third embodiment of the present invention. In FIG. 6, the same reference numerals/characters are given to the same items as those shown in FIG. 1, avoiding redundant description. In FIG. 6, reference numeral 7 denotes an output terminal. The point a or d is viewed from the output side; this is different from that in the first embodiment.

FIG. 7 shows an equivalent circuit provided for the circuit shown in FIG. 6. In FIG. 7, the same reference numerals/characters are given to the same items as those shown in FIG. 6, avoiding redundant description. In FIG. 7, reference numeral 36 denotes a capacitor having a total capacity of the MIM capacity CA and the gate-drain capacity Cgs of the transistor 26. As described above, when the MIM insulation film thickness L increases, the gate-drain capacity Cgd of the transistor 26 increases while the MIM capacity CA decreases. On the other hand, when the MIM insulation film thickness L decreases, the gate-drain capacity Cgd of the transistor 26 decreases while the MIM capacity CA increases. Such way, the MIM capacity CA changes so as to eliminate the change of the gate-drain capacity Cgd of the transistor 26.

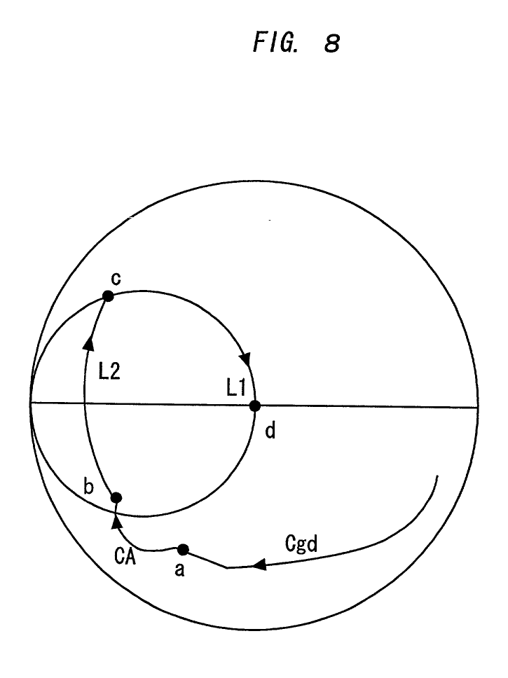

FIG. 8 shows a Smith chart for describing how the output impedance changes. In FIG. 8, the same reference numerals/characters are given to the same items as those shown in FIG. 7, avoiding redundant description. On the Smith chart shown in FIG. 8, the point b for denoting the capacity (CA+Cgd) of the capacitor 36 changes less with respect to the change of the MIM insulation film thickness L, thereby the point d for denoting the output side impedance also changes less. In this case, the open stub capacity L1 does not depend on the MIM insulation film thickness L.

This configuration is also effective not only for the impedance at the output terminal, but also for the impedance when the output side of the transistor is viewed from such a point as a portion between two amplifiers of the circuit.

According to the third embodiment of the present invention described above, therefore, it is possible to obtain the same effect as that of the first embodiment even when the configuration of the first embodiment is modified so that the input side element of the matching circuit is disposed at the output side. That is, because the MIM capacity C1 that changes contrarily to the change of the MIM insulation film thickness L is connected to the output side of the transistor so that the capacity C1 is combined with the output capacity of the transistor, the change of the MIM insulation film thickness L is absorbed automatically. In other words, this third embodiment can realize a matching circuit that can absorb the fluctuation of electric characteristics of the transistor automatically while the change is caused by a change of the MIM insulation film thickness L around the transistor to occur due to the unevenness among fabrication processes.

### Fourth Embodiment

In this fourth embodiment, the input side part of the matching circuit in the above second embodiment is disposed at the output side and the input side capacity Cgs of the transistor in the second embodiment is replaced with the output side capacity Cgd of the transistor. There is no other difference between the second and fourth embodiments.

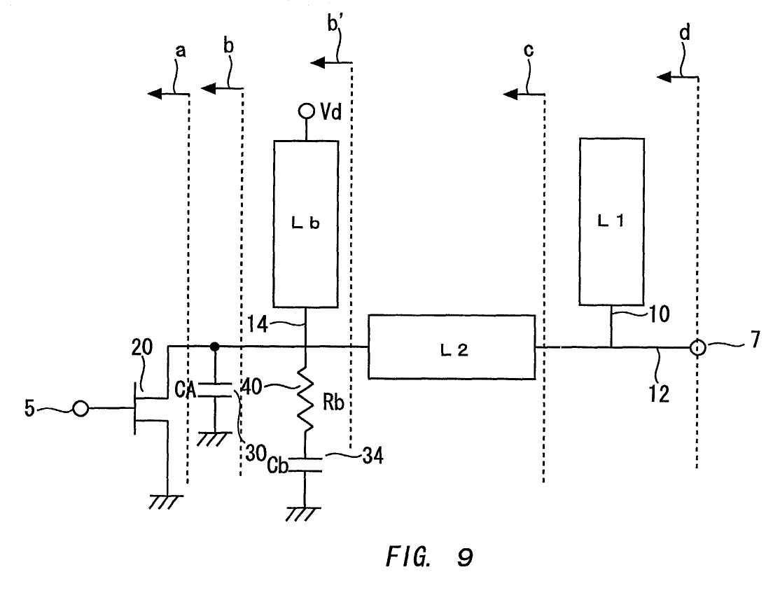

FIG. 9 shows a matching circuit in this fourth embodiment of the present invention. In FIG. 9, the same reference numerals/characters are given to the same items as those shown in FIG. 4, avoiding redundant description. In FIG. 9, reference numeral 7 denotes an output terminal and the points a to d are different from those in the second embodiment in that they are all viewed from the output side. In this case, however, in the case where the point b is shifted to the point b′ located at an inner portion on the Smith chart with use of the bias circuit configured by the resistance value Rb and the capacity Cb, it is possible to obtain a matching circuit that can operate in a wider frequency band just like in the second embodiment.

This configuration is also effective not only for the impedance at the output terminal, but also for the impedance when the output side of the transistor is viewed from such a point as a portion between two amplifiers of a circuit.

According to this fourth embodiment described above, therefore, it is possible to obtain the same effect as that of the first embodiment even when the input side element of the matching circuit in the second embodiment is disposed at the output side. That is, this fourth embodiment can realize a matching circuit that can absorb the fluctuation of electric characteristics of the transistor automatically while the fluctuation of electric characteristics is caused by a change of the MIM insulation film thickness L around the transistor to occur due to the unevenness among fabrication processes. In addition, in the case where a bias circuit is added to the matching circuit, it is possible to realize a high frequency circuit that is stable in operations in a wide frequency band and less affected by the transistor's fluctuation of electric characteristics to be caused by changes of the insulation film thickness around the transistor to occur due to the unevenness among products.

It is also possible to fabricate semiconductor devices with use of any of the matching circuits of the present invention described above. In this case, each of those matching circuits can absorb the fluctuation of electric characteristics of the subject transistor and it can include a capacitor having a capacity that increases/decreases contrarily to the increment/decrement of the parasitic capacity around the transistor. The semiconductor device may be an MMIC or part of the MMIC.

As described above, according to each of the matching circuits of the present invention, because the MIM capacity C1 is connected to the input side of the subject transistor so as to be combined with the input capacity of the transistor, changes of the MIM insulation film thickness L can be absorbed automatically. The MIM capacity C1 changes contrarily to changes of the MIM insulation film thickness L. Consequently, the present invention makes it possible to provide a matching circuit that can protect a high frequency circuit from degradation in both output and efficiency, as well as from an increase of noise, changes of the frequency band, etc. even when the MIM insulation film thickness L around the transistor changes due to the unevenness among fabrication processes. It is thus possible to provide a matching circuit in which the electrical property of the subject transistor never changes among products, as well as to provide a semiconductor device that employs the matching circuit.

In the matching circuit, the parasitic capacity may increase and decrease according to a thickness change of an MIM insulation film formed around the transistor and the capacitor has an MIM capacity to increase and decrease contrarily to the increment and decrement of the parasitic capacity.

In the matching circuit, the capacitor may be provided at an input side of the transistor.

In the matching circuit, the matching circuit may be provided with a predetermined bias circuit disposed in parallel to the capacitor provided at the input side of the transistor.

In the matching circuit, the capacitor may be provided at an output side of the transistor.

In the matching circuit, the matching circuit may be provided with a predetermined bias circuit disposed in parallel to the capacitor provided at the output side of the transistor.

The present invention has been described in detail with respect to various embodiments, and it will now be apparent from the foregoing to those skilled in the art that changes and modifications may be made without departing from the invention in its broader aspects, and it is the invention, therefore, in the appended claims to cover all such changes and modifications as fall within the true spirit of the invention.

The entire disclosure of Japanese Patent Application No. 2001-019243 filed on Jan. 26, 2001 including specification, claims, drawings and summary are incorporated herein by reference in its entirety.

What is claimed is:

1. A matching circuit for absorbing fluctuation of electric characteristics of a transistor, comprising:
a capacitor having a capacity that increases and decreases contrarily to increment and decrement of a parasitic capacity around said transistor.

2. The matching circuit according to claim 1,
wherein said parasitic capacity increases and decreases according to a thickness change of an MIM insulation film formed around said transistor and said capacitor has an MIM capacity to increase and decrease contrarily to the increment and decrement of said parasitic capacity.

3. The matching circuit according to claim 2,
wherein said capacitor is provided at an input side of said transistor.

4. The matching circuit according to claim 3,
wherein said matching circuit is provided with a predetermined bias circuit disposed in parallel to said capacitor provided at the input side of said transistor.

5. The matching circuit according to claim 2,
wherein said capacitor is provided at an output side of said transistor.

6. The matching circuit according to claim 5,
wherein said matching circuit is provided with a predetermined bias circuit disposed in parallel to said capacitor provided at the output side of said transistor.

7. The matching circuit according to claim 1,
wherein said capacitor is provided at an input side of said transistor.

8. The matching circuit according to claim 7,
wherein said matching circuit is provided with a predetermined bias circuit disposed in parallel to said capacitor provided at the input side of said transistor.

9. The matching circuit according to claim 1,
wherein said capacitor is provided at an output side of said transistor.

10. The matching circuit according to claim 9,
wherein said matching circuit is provided with a predetermined bias circuit disposed in parallel to said capacitor provided at the output side of said transistor.

11. A semiconductor device fabricated with use of said matching circuit according to claim 1.

12. A semiconductor device fabricated with use of said matching circuit according to claim 2.
